(19) United States
(12) Patent Application Publication
(10) Pub. No.: US 2009/0128174 A1
(43) Pub. Date: May 21, 2009

(54) Probe card using thermoplastic resin

(75) Inventors: Ho-Joon Park, Seoul (KR); Jun-Rok Oh, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/213,869

(22) Filed: Jun. 25, 2008

(30) Foreign Application Priority Data
Nov. 21, 2007 (KR) 10-2007-0119092

(51) Int. Cl. G01R 1/073

(52) U.S. Cl. 324/754

(57) ABSTRACT

Disclosed is a probe card using thermoplastic resin. The probe card includes: a printed circuit board; a probe head that includes a plurality of terminals disposed on one surface thereof, the terminals being electrically connected to the printed circuit board; and a plurality of probe tips electrically connected to a plurality of the terminals and disposed on the other surface of the probe head, whereas the other surface of the probe head is formed of thermoplastic resin. According to the probe card, it is possible to reduce an inferior goods rate by protecting the probe head even during an etching process.

### CROSS-REFERENCE TO RELATED APPLICATIONS

This application claims the benefit of Korean Patent Application No. 10-2007-0119092, filed with the Korean Intellectual Property Office on Nov. 21, 2007, the disclosure of which is incorporated herein by reference in its entirety.

### BACKGROUND

1. Technical Field

The present invention relates to a probe card, more particularly to a probe card protecting a probe head by using thermoplastic resin.

2. Description of the Related Art

A probe card is a device for checking a semiconductor circuit and a pad that is an output terminal. After wafer manufacturing and before dicing process during semiconductor manufacturing process, probing is performed. That is, a voltage and an electric signal are supplied by contacting a probe tip of the probe card with a pad of chip area, so that good quality products are selected by analyzing such a supplied voltage and electrical signal.

Such a probe card includes a printed circuit board, a probe head and a probe tip. The probe card is manufactured in the manner of connecting a terminal disposed on one surface of the probe head with the printed circuit board and attaching the probe tip on the other surface of the probe head, and is mainly formed of a ceramic substrate and silicon wafers.

While a silicon etching process is included in the process of manufacturing the probe card, an etching solution may etch an undesired part of the probe head during an etching process so that inferior goods may be produced. Accordingly, it is necessary to make a probe card capable of protecting the probe card from the etching solution.

### SUMMARY

The present invention provides a probe card capable of protecting a probe head by using thermoplastic resin.

The present invention also provides a probe card capable of protecting a probe head while normally performing a function of electric connection.

An aspect of the present invention features a probe card including: a printed circuit board; a probe head that includes a plurality of terminals disposed on one surface thereof, the terminals being electrically connected to the printed circuit board; and a plurality of probe tips electrically connected to a plurality of the terminals and disposed on the other surface of the probe head, whereas the other surface of the probe head is formed of thermoplastic resin. In this case, the one surface of the probe head can be also formed of the thermoplastic resin.

Also, the thermoplastic resin is formed of one of materials such as liquid crystal polymer, polyetherimide (PEI), Polyethersulfone (PES), Polyetheretherketone (PEEK) and polytetrafluoroethylene (PTFE), or is formed through combination thereof. One and the other surfaces of the probe head can further include distributed glass clothes.

Another aspect of the present invention features a printed circuit board;

a probe head that includes a plurality of terminals disposed on one surface thereof, the terminals being electrically connected to the printed circuit board, the probe head being formed of thermoplastic resin; and a plurality of probe tips electrically connected to a plurality of the terminals and disposed on the other surface of the probe head.

In this case, the thermoplastic resin is formed of one of materials such as liquid crystal polymer, polyetherimide (PEI), Polyethersulfone (PES), Polyetheretherketone (PEEK) and polytetrafluoroethylene (PTFE), or is formed through combination thereof. The probe head further can include distributed glass clothes.

### BRIEF DESCRIPTION OF THE DRAWINGS

FIG. 1 to FIG. 4 are cross section views illustrating the probe card manufacturing process according to a conventional technology.

FIG. 5 illustrates a cross section view of a probe card according to an embodiment of the present invention.

FIG. 6 illustrates a cross section view of a probe card according to another embodiment of the present invention.

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the spirit and scope of the present invention. In the following description of the present invention, the detailed description of known technologies incorporated herein will be omitted when it may make the subject matter unclear.

Terms such as “first” and “second” can be used in describing various elements, but the above elements shall not be restricted to the above terms. The above terms are used only to distinguish one element from the other. For instance, the first element can be named the second element, and vice versa, without departing the scope of claims of the present invention. The term “and/or” shall include the combination of a plurality of listed items or any of the plurality of listed items.

The terms used in the description are intended to describe certain embodiments only, and shall by no means restrict the present invention. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

Unless otherwise defined, all terms, including technical terms and scientific terms, used herein have the same meaning as how they are generally understood by those of ordinary skill in the art to which the invention pertains. Any term that is defined in a general dictionary shall be construed to have the same meaning in the context of the relevant art, and, unless otherwise defined explicitly, shall not be interpreted to have an idealistic or excessively formalistic meaning.

Hereinafter, an embodiment of the present invention will be described in detail with reference to the accompanying drawings.

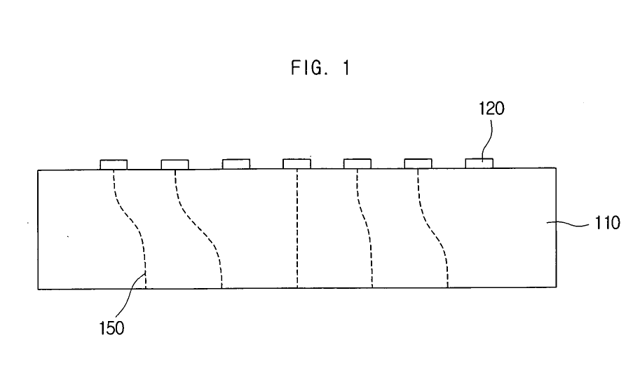

A probe card manufacture process according to a conventional technology and problems subsequent thereto will be described with reference to FIG. 1 to 4. FIG. 1 to FIG. 4 are cross section views illustrating the probe card manufacturing process according to the conventional technology. In this case, it is clearly stated that general elements such as a printed circuit board and fixing means included in the probe card will be omitted for the sake of convenience of description and understanding of the present invention.

Referring to FIG. 1, a plurality of terminals 120 are disposed on one surface of a probe head 110. A plurality of probe tips are disposed on the other surface of the probe head 110. The probe head 110 is equipped with a circuit 150 electrically connecting the probe tip 130 with the terminal 120.

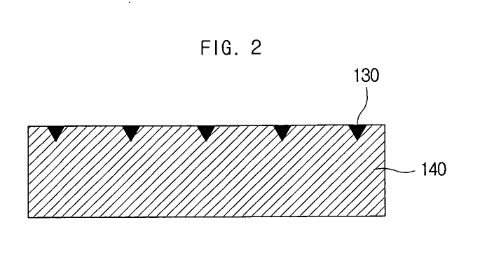

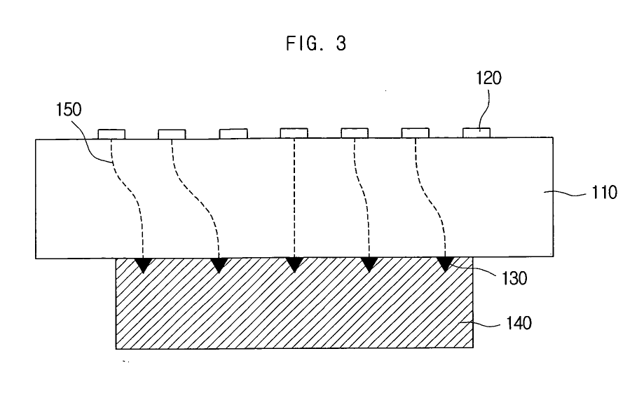

Referring to FIG. 2, a silicon wafer 140 is illustrated in FIG. 2, the silicon wafer being for forming the probe tip 130 to be disposed on the other surface of aforesaid probe head 110. A plurality of grooves are formed on the silicon wafer 140 in the shape of the probe tip 130 in order to form the probe tip 130. Metallic material intended to be the probe tip 130 in the future is poured to each of a plurality of grooves. After the poured metallic material is solidified, the silicon wafer 140 in which the metallic material is solidified in the shape of the probe tip 130 is attached to the other surface of the probe card 110, as illustrated in FIG. 3. In this case, cross-hatched region, i.e., the silicon wafer 140 will be later removed through an etching process.

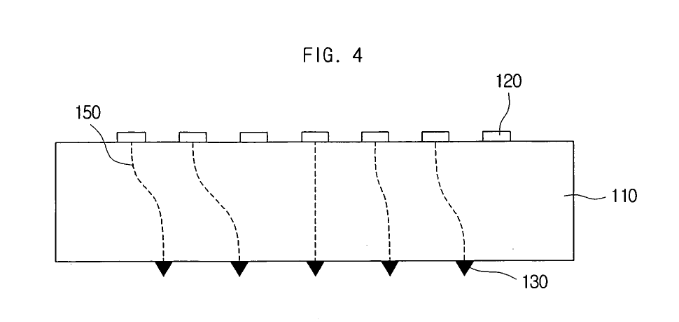

After the silicon wafer 140 attached to the other surface of the probe head 110 is removed through the etching process, it is possible to manufacture a probe card including, as illustrated in FIG. 4, the probe tip 130 and the probe head 110 including a plurality of terminals disposed on one surface thereof.

The etching solution used in such a process may have been affecting a ceramic material probe head 110. In other words, a flatness and pattern that has been already formed may have been affected. Accordingly, there have been problems that the performance of the probe card 110 is degraded or a lot of inferior goods are produced.

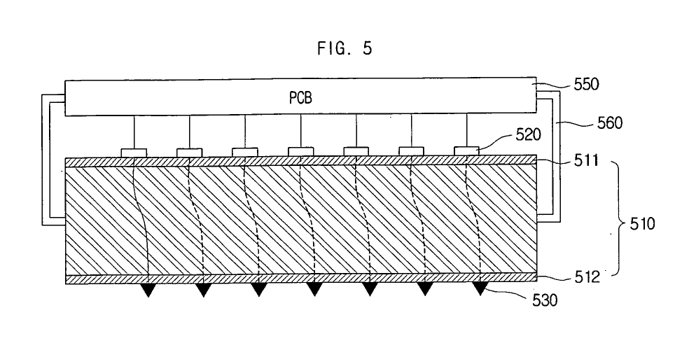

A structure of a probe card according to an embodiment of the present invention will be described with reference to FIG. 5 in the following description. FIG. 5 illustrates a cross section view of a probe card according to an embodiment of the present invention. A probe card according to an embodiment of the present invention includes a printed circuit board (PCB) 550, a terminal 520, a probe head 510, a fixing means 560 and a probe tip 530.

The printed circuit board 550 is electrically connected to a plurality of terminals 520 disposed on one surface of the probe head 510. The printed circuit board 550 receives an electrical signal from the terminals 520 and checks a semiconductor circuit in contact with the probe tip 530 a pad in a semiconductor in a wafer state on the basis of the electric signal.

A plurality of terminals 520 are disposed on one surface of the probe head 510. A plurality of probe tips 530 are provided on the other surface of the probe head. In this case, the probe tip 530 can have an elastic force. Additionally, the terminal 520 is electrically connected with the probe tip 530 through the probe head 510. Accordingly, the probe tip 530 contacts with a surface of an object intended to be checked and receives an electric signal. The received electric signal is transmitted to the printed circuit board 550 through the terminal 520 disposed on the probe head 510. Such an electric signal is analyzed so that it is thereby possible to judge whether or not the object to be checked, for example, a pad is in a normal state. In this case, the probe head 510 can be fixed on the printed circuit board 550 by the fixing means 560.

According to the probe head 510 in accordance with an embodiment of the present invention, one and the other surfaces of the probe head 510 can be formed of thermoplastic resins 511 and 512. It is clearly stated that the formation of the surfaces is a concept including a passivation. Additionally, only one surface of the probe head 510 instead of one and the other surfaces can be formed of the thermoplastic resins 511 and 512. In other words, the other surface on which the probe tip is located should be always protected by the thermoplastic resin.

The thermoplastic resin can be formed of one of materials such as liquid a crystal polymer that is inexpensive and has excellent thermal resistance and excellent intensity, polyetherimide (PEI) known as high functional engineering plastic materials, Polyethersulfone (PES), Polyetheretherketone (PEEK) and polytetrafluoroethylene (PTFE) and the like, and can be also formed through combination thereof.

The probe head 510 is formed of ceramic material. Probe tip 530-shaped grooves are engraved on a silicon mold and metallic material is poured into the grooves and solidified, so that the probe tip 530 is formed.

After the silicon mold including the solidified probe tips 530 is adhered to the probe head 510, the probe card is manufactured by etching the silicon mold. In this case, a silicon etching solution is used so as to etch the silicon mold. The silicon etching solution may affect the probe head 510 formed of ceramic material.

However, as described in the present invention, one and the other surfaces or one and not the other surfaces of the probe head 510 are formed of the thermoplastic resins 511 and 512, the thermoplastic resins are not much affected by the silicon etching solution. Accordingly, the ceramic material probe head 510 is not only protected but also is able to normally perform a function of electric connection, so that the aforesaid problem that the probe head 510 is affected during the etching process can be solved.

In order that one and the other surfaces or one and not the other surfaces of the probe head 510 are form&d of the thermoplastic resin, in accordance with an embodiment of the present invention, it is possible to adhere a thermoplastic resin substrate to one and the other surfaces or one and not the other surfaces of the probe head 510, or to use a method of applying the thermoplastic resin on one and the other surfaces or one and not the other surfaces of the probe head.

In addition, glass clothes can be added to the thermoplastic resin substrate adhered to the surfaces or the thermoplastic resin applied to the surfaces in accordance with an embodiment of the present invention. When the glass clothes are fairly spread to the inside of the thermoplastic resin, there is an advantage of increasing the elasticity and rigidity of the probe head 510.

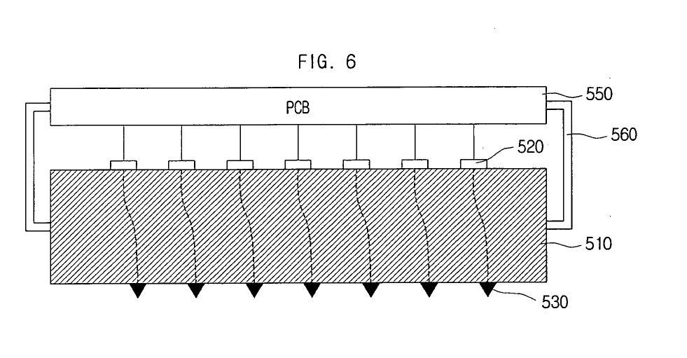

A structure of a probe card according to another embodiment of the present invention will be described in the following description with reference to FIG. 6. FIG. 6 illustrates a cross section view of a probe card according to another embodiment of the present invention. A probe card according to another embodiment of the present invention includes a printed circuit board (PCB) 550, a terminal 520, a probe head 510, a fixing means 560 and a probe tip 530.

In case of the probe card according to another embodiment of the present invention, the entire probe head 510 is formed of the thermoplastic resin in contrast to an embodiment of the present invention illustrated in FIG. 5, in which one and the other surfaces or one and not the other surfaces of the probe head 510 are formed of the thermoplastic resin.

Referring to the probe head 510 of FIG. 6, it can be noted that the entire probe head 510 including one and the other surfaces thereof is formed of the cross-hatched thermoplastic resin.

In this case, as described above, the probe head 510 formed of the thermoplastic resin can include glass clothes of distribution form for the purpose of increasing the elasticity and rigidity of the probe head.

Since the structure of FIG. 6 is the same as that of the probe card according to an embodiment of the present invention illustrated in FIG. 5 with the exception of the difference described above, repetitive descriptions thereof will be omitted for the sake of convenience of description and understanding of the present invention.

While the present invention has been described with reference to exemplary embodiments thereof, it will be understood by those skilled in the art that various changes and modification in forms and details may be made without departing from the spirit and scope of the present invention as defined by the appended claims.

1. A probe card comprising:
a printed circuit board;
a probe head that comprises a plurality of terminals disposed on one surface thereof, the terminals being electrically connected to the printed circuit board; and
a plurality of probe tips electrically connected to a plurality of the terminals and disposed on the other surface of the probe head,
whereas the other surface of the probe head is formed of thermoplastic resin.

2. The probe card of claim 1, wherein the one surface of the probe head is formed of the thermoplastic resin.

3. The probe card of claim 1, wherein one and the other surfaces of the probe head are formed by further comprising distributed glass clothes.

4. The probe card of claim 1, wherein the thermoplastic resin is formed of one of materials such as liquid crystal polymer, polyetherimide (PEI), Polyethersulfone (PES), Polyetheretherketone (PEEK) and polytetrafluoroethylene (PTFE), or is formed through combination thereof.

5. A probe card comprising:
a printed circuit board;
a probe head that comprises a plurality of terminals disposed on one surface thereof, the terminals being electrically connected to the printed circuit board, the probe head being formed of thermoplastic resin; and
a plurality of probe tips electrically connected to a plurality of the terminals and disposed on the other surface of the probe head.

6. The probe card of claim 5, wherein the thermoplastic resin is formed of one of materials such as liquid crystal polymer, polyetherimide (PEI), Polyethersulfone (PES), Polyetheretherketone (PEEK) and polytetrafluoroethylene (PTFE), or is formed through combination thereof.

7. The probe card of claim 5, wherein the probe head further comprises distributed glass clothes.

8. The probe card of claim 2, wherein one and the other surfaces of the probe head are formed by further comprising distributed glass clothes.
